(19) United States
(12) Patent Application Publication
(10) Pub. No.: US 2026/0297396 A1
(43) Pub. Date: Oct. 1, 2026

(54) PRESSURE-SENSITIVE ADHESIVE TAPE

(71) Applicant: NITTO DENKO CORPORATION, Osaka (JP)

(72) Inventors: Mizuho CHIBA, Ibaraki-shi (JP); Hikaru OTA, Ibaraki-shi (JP)

(21) Appl. No.: 19/563,129

(22) Filed: Mar. 11, 2026

(30) Foreign Application Priority Data
Apr. 1, 2025 (JP) 2025-060277

(51) Int. Cl. C09J 7/38; B32B 7/06; B32B 7/12; B32B 27/36; C09J 7/29; C09J 7/40

(52) U.S. Cl. CPC C09J 7/385; B32B 7/06; B32B 7/12; B32B 27/36; C09J 7/29; C09J 7/401; B32B 2307/7376; B32B 2405/00; C09J 2203/326; C09J 2301/302; C09J 2301/414; C09J 2301/416; C09J 2467/006; C09J 2479/00; C09J 2483/005

(57) ABSTRACT

Provided is a pressure-sensitive adhesive tape, which has suppressed contamination of an adherend surface after peeling. The pressure-sensitive adhesive tape includes: a substrate; and a pressure-sensitive adhesive layer formed of an active energy ray-curable pressure-sensitive adhesive. A ratio of a component having a weight-average molecular weight of 1,000 or more and 10,000 or less in a sol content S₂ of the pressure-sensitive adhesive layer after active energy ray irradiation is 5% or less.

### CROSS-REFERENCE TO RELATED APPLICATION(S)

This application claims priority under 35 U.S.C. Section 119 to Japanese Patent Application No. 2025-060277 filed on Apr. 1, 2025, which is herein incorporated by reference.

### BACKGROUND OF THE INVENTION

### Field of the Invention

The present invention relates to a pressure-sensitive adhesive tape.

### Description of the Related Art

A pressure-sensitive adhesive tape has been widely used for the purposes of surface protection and fixation of an adherend. For example, in a processing process for a semiconductor wafer, the pressure-sensitive adhesive tape is used for appropriately holding the semiconductor wafer serving as the adherend in each of a backgrinding step and a dicing step. In recent years, miniaturization and thinning of a chip have been advanced, and hence the pressure-sensitive adhesive tape is required to have such a pressure-sensitive adhesive strength that the semiconductor wafer can be appropriately held even when thinly ground at the time of processing. An easily-peelable pressure-sensitive adhesive tape that can be easily peeled from an adherend without causing an adhesive residue after use has been required as the pressure-sensitive adhesive tape. As such pressure-sensitive adhesive tape, a pressure-sensitive adhesive tape using a UV-curable pressure-sensitive adhesive has been proposed (for example, Japanese Patent Application Laid-open No. 2019-31620).

As a method of joining semiconductors, there is known a method including joining bumps on surfaces thereof to each other with solder. There is a problem in that complex and computationally intensive task processing is difficult for a solder joined semiconductor. As another method of joining semiconductors, there is known hybrid bonding for directly joining metal pads of a semiconductor device to each other.

### SUMMARY OF THE INVENTION

In the hybrid bonding, wafers are directly joined to each other, and hence contamination by a pressure-sensitive adhesive adhering to a surface of a semiconductor wafer and by an adhering substance derived from the pressure-sensitive adhesive may cause a joining failure. Accordingly, a pressure-sensitive adhesive tape, which has more suppressed contamination of an adherend surface after peeling, has been required.

1. According to at least one embodiment of the present invention, there is provided a pressure-sensitive adhesive tape, including: a substrate; and a pressure-sensitive adhesive layer formed of an active energy ray-curable pressure-sensitive adhesive, wherein a ratio of a component having a weight-average molecular weight of 1,000 or more and 10,000 or less in a sol content S₂ of the pressure-sensitive adhesive layer after active energy ray irradiation is 5% or less.

2. In the pressure-sensitive adhesive tape according to the above-mentioned item 1, a molecular weight distribution of a component having a weight-average molecular weight of 1,000 or more and 10,000 or less in a sol content S₁ of the pressure-sensitive adhesive layer before active energy ray irradiation may be 2.0 or less.

3. In the pressure-sensitive adhesive tape according to the above-mentioned item 1 or 2, the active energy ray-curable pressure-sensitive adhesive may contain a polymer having a polymerizable carbon-carbon double bond group at least one of a terminal thereof or a side chain thereof.

4. In the pressure-sensitive adhesive tape according to the above-mentioned item 3, the polymer having a polymerizable carbon-carbon double bond group at least one of a terminal thereof or a side chain thereof may have a weight-average molecular weight of from 300,000 to 1,500,000.

5. In the pressure-sensitive adhesive tape according to the above-mentioned item 3 or 4, the polymer having a polymerizable carbon-carbon double bond group at least one of a terminal thereof or a side chain thereof may have a molecular weight distribution of 5.0 or less.

6. In the pressure-sensitive adhesive tape according to any one of the above-mentioned items 1 to 5, a pressure-sensitive adhesive strength of the pressure-sensitive adhesive layer to a silicon wafer after active energy ray irradiation may be 0.1 N/20 mm or less.

7. In the pressure-sensitive adhesive tape according to any one of the above-mentioned items 1 to 6, a gel fraction G₂ of the pressure-sensitive adhesive layer after active energy ray irradiation may be 90% or more.

8. In the pressure-sensitive adhesive tape according to any one of the above-mentioned items 3 to 7, the polymer having a polymerizable carbon-carbon double bond group at least one of a terminal thereof or a side chain thereof may be an acrylic polymer.

9. In the pressure-sensitive adhesive tape according to any one of the above-mentioned items 1 to 8, the active energy ray-curable pressure-sensitive adhesive may further contain an isocyanate-based cross-linking agent.

10. In the pressure-sensitive adhesive tape according to any one of the above-mentioned items 1 to 9, the substrate may be a substrate formed of a polyester-based resin.

11. In the pressure-sensitive adhesive tape according to any one of the above-mentioned items 1 to 10, the substrate may further include an anchor coat layer, and the pressure-sensitive adhesive layer may be laminated on the anchor coat layer.

12. In the pressure-sensitive adhesive tape according to the above-mentioned item 11, the anchor coat layer may contain a thermosetting resin.

13. In the pressure-sensitive adhesive tape according to the above-mentioned item 12, the anchor coat layer may contain a thermosetting resin having an oxazoline group.

14. The pressure-sensitive adhesive tape according to any one of the above-mentioned items 1 to 13 may further include a release liner laminated on the pressure-sensitive adhesive layer, and the release liner may include a release treatment layer having a thickness of 0.05 μm or less.

15. In the pressure-sensitive adhesive tape according to the above-mentioned item 14, an amount of silicone present on a surface of the pressure-sensitive adhesive layer after peeling of the release liner may be 2.0 mg/m² or less.

16. In the pressure-sensitive adhesive tape according to the above-mentioned item 14 or 15, the release liner may have a liner peel strength of 0.2 N/50 mm or less.

17. The pressure-sensitive adhesive tape according to any one of the above-mentioned items 1 to 16, wherein the pressure-sensitive adhesive tape may be used for a semiconductor wafer processing process.

### BRIEF DESCRIPTION OF THE DRAWINGS

FIG. 1 is a schematic sectional view of a pressure-sensitive adhesive tape according to at least one embodiment of the present invention.

FIG. 2 is a schematic sectional view of a pressure-sensitive adhesive tape with a release liner according to at least one embodiment of the present invention.

### DESCRIPTION OF THE EMBODIMENTS

### A. Overall Configuration of Pressure-sensitive Adhesive Tape

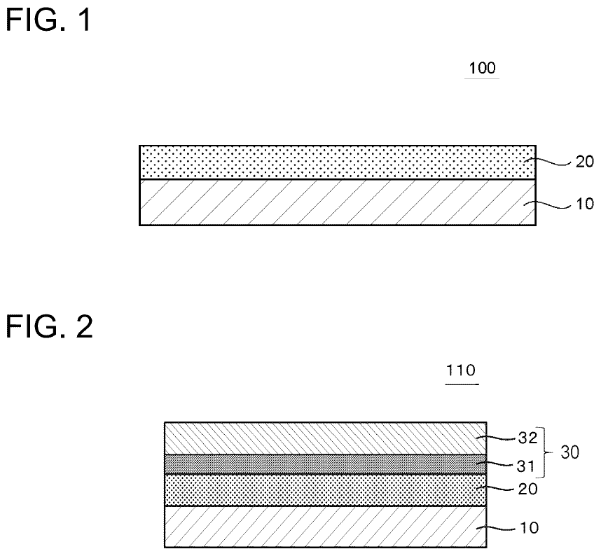

A pressure-sensitive adhesive tape according to at least one embodiment of the present invention includes: a substrate; and a pressure-sensitive adhesive layer formed of an active energy ray-curable pressure-sensitive adhesive. FIG. 1 is a schematic sectional view of a pressure-sensitive adhesive tape according to at least one embodiment of the present invention. In the illustrated example, a pressure-sensitive adhesive tape 100 includes a substrate 10 and a pressure-sensitive adhesive layer 20. The substrate may include an anchor coat layer (not shown). The anchor coat layer may be formed between the substrate 10 and the pressure-sensitive adhesive layer 20. In at least one embodiment of the present invention, in practical use, a release liner may be temporarily attached to the pressure-sensitive adhesive layer 20 of the pressure-sensitive adhesive tape 100 in a peelable manner until the tape is used. FIG. 2 is a schematic sectional view of a pressure-sensitive adhesive tape with a release liner according to at least one embodiment of the present invention. In the illustrated example, a pressure-sensitive adhesive tape 110 with a release liner includes a release liner 30 laminated on the pressure-sensitive adhesive layer 20. The release liner 30 typically includes a release treatment layer 31 and a substrate film 32.

In the pressure-sensitive adhesive layer, a ratio of a component having a weight-average molecular weight (hereinafter also referred to as “Mw”) of 1,000 or more and 10,000 or less in a sol content S₂ after active energy ray irradiation is 5% or less, preferably 4% or less, still more preferably 3% or less with respect to the sol content S₂. The ratio of the component having a Mw of 1,000 or more and 10,000 or less in the sol content S₂ is preferably as small as possible, and may be 0%. Herein, the ratio of the component having a Mw of 1,000 or more and 10,000 or less in the sol content S₂ refers to a ratio of the component having a Mw of 1,000 or more and 10,000 or less in the sol content S₂ measured with a GPC including a refractive index detector (RI detector).

### <Measurement of Ratio of Component Having Weight-Average Molecular Weight of 1,000 or More and 10,000 or Less in Sol Content S₂>

A pressure-sensitive adhesive tape including a release liner bonded to a pressure-sensitive adhesive layer is cut out into a size measuring 5 cm by 5 cm to provide a sample. The pressure-sensitive adhesive tape is irradiated with an active energy ray (e.g., UV light (UV), integrated light quantity: 460 mJ/cm² (converted to a wavelength of 365 nm)) from a substrate side. After that, the release liner is peeled from the sample. A sample is collected from the pressure-sensitive adhesive layer of the pressure-sensitive adhesive tape after active energy ray irradiation. Tetrahydrofuran (THF) is added to the sample so that a sol content S₂ concentration becomes 0.1 wt % to prepare a sample, and the sample is left to stand still for 1 day for dissolution. Next, the resultant sample is filtered through use of a 0.45 μm membrane filter. The filtrate is subjected to GPC measurement under the following conditions, and an area ratio of a component having a weight-average molecular weight (Mw) of 1,000 or more and 10,000 or less is calculated from the obtained molecular weight distribution curve. The sol content concentration is calculated by the following equation. A method of measuring a gel fraction G₂ is as described later.

Sol content S₂ concentration (wt %)=100 (wt %)-gel fraction G₂ (wt %)

### <GPC Measurement Conditions>

Apparatus: manufactured by Agilent Technologies, Inc., product
name: “1260 Infinity” and a product equivalent thereto
Column: manufactured by Tosoh Corporation, product name: “TSKgel GMH-H(S)” and a product equivalent thereto
Flow rate: 0.5 ml/min
Column temperature: 40° C.
Eluent: THF
Injection amount: 100 μL
Injected sample concentration: 0.1 wt %
Detector: RI detector

The pressure-sensitive adhesive tape may further include any appropriate layer other than the substrate and the pressure-sensitive adhesive layer. For example, the pressure-sensitive adhesive tape may further include an intermediate layer and an antistatic layer. When the pressure-sensitive adhesive tape includes an intermediate layer, its embeddability of the pressure-sensitive adhesive tape can be improved. When the pressure-sensitive adhesive tape includes an antistatic layer, electrostatic breakdown of a semiconductor element due to static electricity at the time of peeling of the pressure-sensitive adhesive tape can be prevented.

A thickness of the pressure-sensitive adhesive tape may be set to any appropriate range. The thickness of the pressure-sensitive adhesive tape is preferably from 10 μm to 1,000 μm, more preferably from 30 μm to 300 μm, still more preferably from 40 μm to 200 μm.

### B. Substrate

The substrate may be formed of any appropriate resin. Specific examples of the resin for forming the substrate include polyester-based resins, such as polyethylene terephthalate (PET), polyethylene naphthalate (PEN), polybutylene terephthalate (PBT), and polybutylene naphthalate (PBN), polyolefin-based resins, such as an ethylene-vinyl acetate copolymer, an ethylene-methyl methacrylate copolymer, polyethylene, polypropylene, and an ethylene-propylene copolymer, polyvinyl alcohol, polyvinylidene chloride, polyvinyl chloride, a vinyl chloride-vinyl acetate copolymer, polyvinyl acetate, polyamide, polyimide, celluloses, a fluorine-based resin, polyether, polystyrene-based resins such as polystyrene, polycarbonate, and polyether sulfone. Of those, polyester-based resins, such as polyethylene terephthalate, polyethylene naphthalate, polybutylene terephthalate, and polybutylene naphthalate, are preferably used.

The substrate may further contain another component to the extent that the effects of the present invention are not impaired. Examples of the other component include an antioxidant, a UV absorber, a light stabilizer, and a heat stabilizer. The other component may be used in any appropriate amount in accordance with purposes.

The substrate preferably further includes an anchor coat layer. When the substrate includes an anchor coat layer, adhesiveness between the pressure-sensitive adhesive layer and the substrate can be maintained even after active energy ray irradiation. The anchor coat layer preferably contains a thermosetting resin. Any appropriate resin may be used as the thermosetting resin. Examples thereof include a phenol resin, an epoxy resin, a melamine resin, a urea resin, an unsaturated polyester resin, an alkyd resin, a silicone resin, polyurethane, a thermosetting polyimide, and an acrylic resin. Of those, an acrylic resin is preferably used. The thermosetting resin may have a group containing a polymerizable carbon-carbon double bond (polymerizable carbon-carbon double bond group), such as an acryloyl group, a methacryloyl group, a vinyl group, or an aryl group. The thermosetting resins may be used alone or in combination thereof.

The thermosetting resin preferably has a reactive functional group. Examples of the reactive functional group include a carboxyl group, an amino group, a hydroxy group, a glycidyl group, an isocyanate group, and an oxazoline group. When the thermosetting resin having a reactive functional group is used, a cross-linking agent capable of reacting with the reactive functional group may be further added. When the cross-linking agent capable of reacting with the reactive functional group is added, the cohesiveness of the anchor coat layer can be adjusted, and adhesiveness to the active energy ray-curable pressure-sensitive adhesive and blocking resistance can be easily adjusted.

Examples of the cross-linking agent capable of reacting with the reactive functional group include: aziridine-based cross-linking agents, such as N,N′-diphenylmethane-4,4′-bis(1-aziridinecarboxamide), trimethylolpraopane-tri-β-aziridinylpropionate, tetramethylolmethane-tri-β-aziridinylpropionate, N,N′-toluene-2,4-bis(1-aziridinecarboxamide), and triethylene melamine; epoxy-based cross-linking agents, such as a bisphenol A-type epoxy compound, a bisphenol F-type epoxy compound, 1,3-bis(N,N-diglycidylaminomethyl) benzene, 1, 3-bis(N,N-diglycidylaminomethyl)toluene, and N,N,N′,N′-tetraglycidyl-4,4-diaminodiphenylmethane; isocyanate-based cross-linking agents, such as tolylene diisocyanate (TDI), hexamethylene diisocyanate (HMDI), isophorone diisocyanate (IPDI), xylylene diisocyanate (XDI), hydrogenated tolylene diisocyanate, diphenylmethane diisocyanate and a hydrogenated product thereof, polymethylene polyphenyl polyisocyanate, naphthylene-1,5-diisocyanate, a polyisocyanate prepolymer, and polymethylolpropane-modified TDI; and metal chelate-based cross-linking agents, which are chelate compounds each including a metal atom, such as aluminum, zirconium, titanium, zinc, iron, or tin.

The content of the cross-linking agent is preferably 1 part by weight (in terms of solid content) or more, more preferably from 5 parts by weight to 70 parts by weight (in terms of solid content), still more preferably from 5 parts by weight to 50 parts by weight (in terms of solid content) with respect to 100 parts by weight (in terms of solid content) of the thermosetting resin. When the content of the cross-linking agent falls within the above-mentioned ranges, the anchor coat layer can be kept at an appropriate hardness, and satisfactory adhesiveness to the substrate can be obtained.

The anchor coat layer may further contain any appropriate other component. Examples of the other component include a plasticizer, a filler, a pigment, an antistatic agent, a flame retardant, a photopolymerization initiator, a leveling agent, and a coupling agent. The other component is used at any appropriate content. Those other components may be used alone or in combination thereof.

The thickness of the anchor coat layer may be set to any appropriate thickness. The thickness of the anchor coat layer is, for example, from 0.1 μm to 10 μm, preferably from 0.1 μm to 5 μm. When the thickness falls within the above-mentioned ranges, the anchor coat layer can efficiently absorb shrinkage at the time of the curing of the pressure-sensitive adhesive layer, and thus peeling of the anchor coat layer from the substrate can be suppressed. In addition, blocking can be suppressed.

In at least one embodiment of the present invention, the substrate has an antistatic function. When the substrate has an antistatic function, generation of static electricity at the time of peeling of the pressure-sensitive adhesive tape is suppressed, and breakdown of a circuit by static electricity and adhesion of foreign matter can be prevented. The substrate may have an antistatic function by being formed of a resin containing an antistatic agent, or may have an antistatic function by applying a composition containing an antistatic component, such as a conductive polymer, an organic or inorganic conductive substance, or an antistatic agent, to any appropriate film to form an antistatic layer. When the substrate includes the antistatic layer, an intermediate layer is preferably laminated on a surface on which the antistatic layer is formed. When the substrate has an antistatic function, the substrate has a surface resistance value of, for example, from 1.0×10²Ω/□ to 1.0×10¹³Ω/□.

The thickness of the substrate may be set to any appropriate value. The thickness of the substrate is preferably from 10 μm to 200 μm, more preferably from 20 μm to 150 μm.

### C. Pressure-sensitive Adhesive Layer

The pressure-sensitive adhesive layer may be formed by using any appropriate active energy ray-curable pressure-sensitive adhesive. The pressure-sensitive adhesive typically contains a base polymer. When the pressure-sensitive adhesive layer is formed of the active energy ray-curable pressure-sensitive adhesive, a pressure-sensitive adhesive tape for semiconductor wafer processing excellent in easy peelability can be obtained. As described above, the ratio of the component having a Mw of 1,000 or more and 10,000 or less in the sol content S₂ of the pressure-sensitive adhesive layer after active energy ray irradiation is 5% or less. When the ratio of the component having a weight-average molecular weight of 1,000 or more and 10,000 or less in the sol content S₂ of the pressure-sensitive adhesive layer falls within the above-mentioned range, contamination of the adherend surface after the peeling of the pressure-sensitive adhesive tape can be further suppressed.

The molecular weight distribution of the component having a weight-average molecular weight of 1,000 or more and 10,000 or less in the sol content S₁ before active energy ray irradiation is preferably 2.0 or less, more preferably 1.9 or less, still more preferably 1.8 or less. The molecular weight distribution of the sol content S₁ before active energy ray irradiation is, for example, 1.0 or more. Herein, the molecular weight distribution of the component having a weight-average molecular weight of 1,000 or more and 10,000 or less in the sol content S₁ refers to a value obtained by calculating a number-average molecular weight (Mn) and a weight-average molecular weight (Mw) under the following conditions and calculating a ratio Mw/Mn.

### <Measurement of Molecular Weight Distribution of Sol Content S₁>

A pressure-sensitive adhesive tape including a release liner bonded to a pressure-sensitive adhesive layer is cut out into a size measuring 5 cm by 5 cm, and then the release liner is peeled from the sample. The pressure-sensitive adhesive is collected from the pressure-sensitive adhesive layer of the pressure-sensitive adhesive tape. Tetrahydrofuran (THF) is added to the pressure-sensitive adhesive so that a sol content S₁ concentration becomes 0.1 wt % to prepare a sample, and the sample is left to stand still for 1 day for dissolution. Next, the resultant sample is filtered through use of a 0.45 μm membrane filter. The filtrate is subjected to GPC measurement under the following conditions, and the molecular weight distribution is determined from the obtained molecular weight distribution curve. The sol content S₁ concentration is calculated by the following equation. A method of measuring a gel fraction G₁ is as described later.

$$Sol content {S}_{1} concentration ( wt \% ) = 100 ( wt \% ) - gel fraction {G}_{1} ( wt \% )$$

### <GPC Measurement Conditions>

Apparatus: manufactured by Agilent Technologies, Inc., product
name: “1260 Infinity” and a product equivalent thereto
Column: manufactured by Tosoh Corporation, product name: “TSKgel GMH-H(S)” and a product equivalent thereto
Flow rate: 0.5 ml/min
Column temperature: 40° C.
Eluent: THF
Injection amount: 100 μL
Injected sample concentration: 0.1 wt %
Detector: RI detector

A gel fraction G₂ of the pressure-sensitive adhesive after active energy ray irradiation is preferably 90% or more, more preferably 93% or more, still more preferably 95% or more. The gel fraction G₂ of the pressure-sensitive adhesive is preferably as high as possible. When the gel fraction G₂ of the pressure-sensitive adhesive falls within the above-mentioned ranges, the pressure-sensitive adhesive tape after active energy ray irradiation can be easily peeled from an adherend. Herein, the gel fraction G₂ of the pressure-sensitive adhesive after active energy ray irradiation refers to a value measured by the following method.

<Method of measuring Gel Fraction G₂>

A pressure-sensitive adhesive tape including a release liner bonded to a pressure-sensitive adhesive layer is cut out into a size measuring 5 cm by 5 cm to provide a sample. The pressure-sensitive adhesive tape is irradiated with UV light (UV) (integrated light quantity: 460 mJ/cm² (converted to wavelength of 365 nm)) from a substrate side. After that, the release liner is peeled from the sample. Next, about 0.1 part by weight of the pressure-sensitive adhesive is scraped off from the sample after the UV irradiation. After that, the cut-out sample is wrapped, in a drawstring bag shape, with a porous polytetrafluoroethylene film (manufactured by Nitto Denko Corporation, product name: “NITOFLON (trademark) NTF1122”, porosity: 75%, thickness: 85 μm, or a product equivalent thereto) having an average pore diameter of 0.2 μm, whose weight has been measured in advance, and a kite string (Wg₁), and a total weight (Wg₂) is measured. Separately, the weight of the substrate of the pressure-sensitive adhesive tape is calculated from its area and the specific gravity of a material for the substrate (Wg₃). The bag is immersed in 50 mL of ethyl acetate and held at room temperature (about 23° C.) for 7 days so that only a sol component in the pressure-sensitive adhesive layer is eluted out of the film. After that, the bag is taken out from ethyl acetate, and ethyl acetate adhering to the outer surface of the bag is wiped off. Next, the bag is dried at 130° C. for 2 hours, and the weight (Wg₄) of the bag is measured. The measured values Wg₁ to Wg₄ are substituted into the following equation to calculate a gel fraction ratio of the pressure-sensitive adhesive layer.

$$Gel fraction ( \% ) = [ ( {Wg}_{4} - {Wg}_{1} - {Wg}_{3} ) / ( {Wg}_{2} - {Wg}_{1} - {Wg}_{3} ) ]$$

A gel fraction G₁ of the pressure-sensitive adhesive before active energy ray irradiation is preferably 50% or more, more preferably 80% or more, still more preferably 90% or more. The gel fraction G₁ of the pressure-sensitive adhesive is, for example, 95% or less. When the gel fraction G₁ of the pressure-sensitive adhesive before active energy ray irradiation falls within the above-mentioned ranges, an initial pressure-sensitive adhesive strength and cohesive strength are sufficiently exhibited, and a wafer can be sufficiently fixed at the time of processing. Herein, the gel fraction G₁ of the pressure-sensitive adhesive before active energy ray irradiation refers to a value measured by the same method as that described above except that a sample used for the measurement is collected from the pressure-sensitive adhesive layer of the pressure-sensitive adhesive tape from which the release liner has been peeled.

Any appropriate pressure-sensitive adhesive may be used as the active energy ray-curable pressure-sensitive adhesive. For example, a pressure-sensitive adhesive obtained by adding a UV-curable monomer and/or oligomer to any appropriate pressure-sensitive adhesive, such as an acrylic pressure-sensitive adhesive, a rubber-based pressure-sensitive adhesive, a silicone-based pressure-sensitive adhesive, or a polyvinyl ether-based pressure-sensitive adhesive, may be used, or a pressure-sensitive adhesive obtained by using, as a base polymer, a polymer having a polymerizable carbon-carbon double bond introduced into a side chain thereof and/or a terminal thereof may be used. Of those, a pressure-sensitive adhesive obtained by using, as a base polymer, a polymer having a polymerizable carbon-carbon double bond introduced into a side chain thereof and/or a terminal thereof is preferably used. When the polymer having a polymerizable carbon-carbon double bond introduced into a side chain thereof and/or a terminal thereof is used, a low-molecular weight component, such as an oligomer formed at the time of the polymerization of the base polymer, tends to precipitate easily as a particle after active energy ray irradiation. In the pressure-sensitive adhesive tape according to at least one embodiment of the present invention, the precipitation of the low-molecular weight component is suppressed even when the polymer having a polymerizable carbon-carbon double bond introduced into a side chain thereof and/or a terminal thereof is used, and as a result, contamination of an adherend can be suppressed.

When the polymer having a polymerizable carbon-carbon double bond introduced into a side chain thereof and/or a terminal thereof is used, a polymer having a polymerizable carbon-carbon double bond introduced into a side chain thereof and/or a terminal thereof and having a pressure-sensitive adhesive property is used as the base polymer. Examples of such polymer include polymers each having a polymerizable carbon-carbon double bond introduced into a resin, such as an acrylic resin, a vinyl alkyl ether-based resin, a silicone-based resin, a polyester-based resin, a polyamide-based resin, a urethane-based resin, or a styrene-diene block copolymer. Of those, an acrylic resin having a polymerizable carbon-carbon double bond introduced thereinto is preferably used. When the acrylic resin is used, a pressure-sensitive adhesive tape, in which the storage modulus of elasticity and tensile modulus of elasticity of the pressure-sensitive adhesive layer are easily adjusted, and which has an excellent balance between pressure-sensitive adhesive strength and peelability, can be obtained. Further, contamination of a semiconductor wafer by a component derived from the pressure-sensitive adhesive can be reduced.

### C-1. Base Polymer

Any appropriate polymer may be used as the base polymer. The base polymer may be obtained by polymerizing any appropriate monomer composition. As described above, a (meth)acrylic polymer is preferably used as the base polymer. Herein, the term “(meth)acryl” refers to “acryl” and/or “methacryl”.

The (meth)acrylic polymer contains a constituent component derived from an alkyl (meth)acrylate. Examples of the alkyl (meth)acrylate include (meth)acrylic acid C1 to C20 alkyl esters, such as methyl (meth)acrylate, ethyl (meth)acrylate, propyl (meth)acrylate, isopropyl (meth)acrylate, n-butyl (meth)acrylate, isobutyl (meth)acrylate, s-butyl (meth)acrylate, pentyl (meth)acrylate, isopentyl (meth)acrylate, hexyl (meth)acrylate, heptyl (meth)acrylate, 2-ethylhexyl (meth)acrylate, octyl (meth)acrylate, isooctyl (meth)acrylate, nonyl (meth)acrylate, isononyl (meth)acrylate, decyl (meth)acrylate, isodecyl (meth)acrylate, undecyl (meth)acrylate, dodecyl (meth)acrylate, tridecyl (meth)acrylate, tetradecyl (meth)acrylate, pentadecyl (meth)acrylate, hexadecyl (meth)acrylate, heptadecyl (meth)acrylate, octadecyl (meth)acrylate, nonadecyl (meth)acrylate, and eicosyl (meth)acrylate.

The (meth)acrylic polymer may contain a constituent unit corresponding to another monomer copolymerizable with the alkyl (meth)acrylate as required for the purpose of modification of cohesive strength, heat resistance, cross-linkability, or the like. Examples of such monomer include: carboxyl group-containing monomers, such as (meth)acrylic acid, carboxyethyl (meth)acrylate, carboxypentyl (meth)acrylate, itaconic acid, maleic acid, fumaric acid, and crotonic acid; acid anhydride monomers, such as maleic anhydride and itaconic anhydride; hydroxy group-containing monomers, such as hydroxyethyl acrylate, 2-hydroxyethyl (meth)acrylate, 2-hydroxypropyl (meth)acrylate, 4-hydroxybutyl (meth)acrylate, and N-(2-hydroxyethyl)acrylamide; sulfonic acid group-containing monomers, such as styrenesulfonic acid and allylsulfonic acid; nitrogen-containing monomers, such as N-vinylpyrrolidone, methylvinylpyrrolidone, vinylpyridine, vinylpiperidone, vinylpyrimidine, vinylpiperazine, vinylpyrazine, vinylpyrrole, vinylimidazole, vinyloxazole, vinylmorpholine, (meth)acryloylmorpholine, N-vinylcarboxylic acid amides, N-vinylcaprolactam, N-(2-hydroxyethyl)acrylamide, (meth)acrylamide, and N,N-dimethyl (meth)acrylamide; aminoalkyl (meth)acrylate-based monomers such as aminoethyl (meth)acrylate; alkoxyalkyl (meth)acrylate-based monomers such as methoxyethyl (meth)acrylate; maleimide-based monomers, such as N-cyclohexylmaleimide and N-isopropylmaleimide; itaconimide-based monomers, such as N-methylitaconimide and N-ethylitaconimide; succinimide-based monomers; vinyl-based monomers, such as vinyl acetate, vinyl propionate, N-vinylpyrrolidone, and methylvinylpyrrolidone; cyanoacrylate monomers, such as acrylonitrile and methacrylonitrile; epoxy group-containing acrylic monomers such as glycidyl (meth)acrylate; glycol-based acrylic ester monomers, such as polyethylene glycol (meth)acrylate and polypropylene glycol (meth)acrylate; acrylic acid ester-based monomers each having a heterocycle, a halogen atom, or a silicon atom, such as tetrahydrofurfuryl (meth)acrylate, fluorine (meth)acrylate, and silicone (meth)acrylate; olefin-based monomers, such as isoprene, butadiene, and isobutylene; and vinyl ether-based monomers such as vinyl ether. Those monomer components may be used alone or in combination thereof. The content ratio of the constituent unit derived from the other monomer is preferably from 1 part by weight to 50 parts by weight, more preferably from 5 parts by weight to 25 parts by weight in 100 parts by weight of the total amount of monomer components.

In at least one embodiment of the present invention, the content of the hydroxy group-containing monomer is preferably from 5 parts by weight to 50 parts by weight, more preferably from 8 parts by weight to 30 parts by weight, still more preferably from 10 parts by weight to 30 parts by weight in 100 parts by weight of the total amount of monomer components. Any appropriate monomer, for example, the monomer given as an example in the foregoing, may be used as the hydroxy group-containing monomer. Of those, hydroxyethyl acrylate is preferably used. When hydroxyethyl acrylate is used, the amount of shrinkage after curing can be further increased. As a result, peeling can be performed more easily, and the amount of an adhering substance on the adherend after peeling can be suppressed.

The polymer having a polymerizable carbon-carbon double bond introduced into a side chain thereof and/or a terminal thereof may be obtained by any appropriate method. The polymer may be obtained by, for example, subjecting a resin obtained by any appropriate polymerization method and a compound having a polymerizable carbon-carbon double bond to a reaction (e.g., a condensation reaction or an addition reaction). Specifically, when the acrylic resin is used, the (meth)acrylic polymer having a polymerizable carbon-carbon double bond introduced thereinto may be obtained by polymerizing a (meth)acrylic polymer (copolymer) having a constituent unit derived from a monomer having any appropriate functional group in any appropriate solvent, and then performing a reaction between a functional group of the (meth)acrylic polymer and the compound having a polymerizable carbon-carbon double bond capable of reacting with the functional group. The amount of the compound having a polymerizable carbon-carbon double bond to be subjected to the reaction is preferably from 4 parts by weight to 30 parts by weight, more preferably from 4 parts by weight to 20 parts by weight with respect to 100 parts by weight of the above-mentioned polymer. Any appropriate solvent may be used as the solvent. Examples thereof include various organic solvents, such as ethyl acetate, methyl ethyl ketone, and toluene.

When the (meth)acrylic polymer and the compound having a polymerizable carbon-carbon double bond are subjected to a reaction as described above, the polymer and the compound having a polymerizable carbon-carbon double bond preferably have functional groups capable of reacting with each other. The combination of the functional groups is, for example, a carboxyl group/an epoxy group, a carboxyl group/an aziridine group, or a hydroxy group/an isocyanate group. Of those combinations of the functional groups, a combination of a hydroxy group and an isocyanate group is preferred from the viewpoint of ease of reaction tracking.

When a compound having a polymerizable carbon-carbon double bond and an isocyanate group is used, the polymerizable carbon-carbon double bond is introduced into preferably from 40 mol % to 95 mol %, more preferably from 50 mol % to 90 mol %, still more preferably from 50 mol % to 80 mol % of hydroxy groups of the base monomer. When the introduction amount of the polymerizable carbon-carbon double bond falls within the above-mentioned ranges, the amount of an adhering substance on the adherend after peeling can be suppressed.

Examples of the compound having a polymerizable carbon-carbon double bond include 2-isocyanatoethyl methacrylate, methacryloyl isocyanate, 2-methacryloyloxyethyl isocyanate (i.e., 2-isocyanatoethyl methacrylate), and m-isopropenyl-α,α-dimethylbenzyl isocyanate.

The (meth)acrylic polymer has a weight-average molecular weight of preferably 300,000 or more, more preferably 400,000 or more, still more preferably from 500,000 to 1,500,000, particularly preferably from 600,000 to 900,000. When the weight-average molecular weight falls within such ranges, bleeding of a low-molecular weight component can be prevented, and hence a pressure-sensitive adhesive that has a low contamination property can be obtained. In addition, the molecular weight distribution (Mw/Mn) of the (meth)acrylic polymer is preferably 5.0 or less, more preferably 4.8 or less, still more preferably 4.5 or less. The Mw/Mn is, for example, 1.0 or more. The weight-average molecular weight and the number-average molecular weight may be determined by gel permeation chromatography measurement (solvent: tetrahydrofuran, in terms of polystyrene).

The (meth)acrylic polymer may be obtained by polymerizing the above-mentioned monomer composition by any appropriate method. Examples thereof include solution polymerization, suspension polymerization, emulsion polymerization, and bulk polymerization.

A solid content concentration of the monomer composition may be set to any appropriate value. In at least one embodiment of the present invention, a monomer composition having a high solid content concentration is preferred. The solid content concentration may be set to any appropriate value in accordance with the solvent to be used. For example, when ethyl acetate is used, the concentration may be set to from 30 wt % to 50 wt %, and when toluene is used, the concentration may be set to from 50 wt % to 80 wt %.

A polymerization temperature and a polymerization time may be set to any appropriate values in accordance with the kind of the polymerization initiator to be used. For example, when an azo polymerization initiator such as 2,2′-azobisbutyronitrile is used, the polymerization temperature may be set to preferably from 55° C. to 65° C., more preferably from 55° C. to 62° C. In addition, when the azo polymerization initiator is used, the polymerization time may be preferably from 3 hours to 8 hours, more preferably from 3 hours to 5 hours. In addition, when an organic peroxide-based polymerization initiator such as benzoyl peroxide is used, the polymerization temperature may be set to preferably from 60° C. to 70° C., more preferably from 60° C. to 67° C. In addition, when the organic peroxide-based polymerization initiator is used, the polymerization time may be preferably from 3 hours to 8 hours, more preferably from 3 hours to 5 hours.

The polymerization step may further include using any appropriate additive. For example, a chain transfer agent is used as the additive. When the chain transfer agent is used, a polymer having a narrower molecular weight distribution can be obtained.

The polymerization of the monomer composition is preferably performed in one stage, and an aging step is preferably not performed. When the aging step is not performed, the formation of low-molecular oligomers is suppressed, and an adhering substance on the adherend after peeling can be suppressed. Residual monomers may be reduced in ratio by being volatilized in the coating step of the pressure-sensitive adhesive tape.

### C-2. Photopolymerization Initiator

The active energy ray-curable pressure-sensitive adhesive for forming the pressure-sensitive adhesive layer preferably further contains a photopolymerization initiator. Any appropriate initiator may be used as the photopolymerization initiator. Examples of the photopolymerization initiator include: acyl phosphine oxide-based photopolymerization initiators, such as ethyl 2,4,6-trimethylbenzylphenyl phosphinate and (2,4,6-trimethylbenzoyl)-phenylphosphine oxide; α-ketol-based compounds, such as 4-(2-hydroxyethoxy)phenyl(2-hydroxy-2-propyl) ketone, α-hydroxy-α,α′-dimethylacetophenone, 2-methyl-2-hydroxypropiophenone, and 1-hydroxycyclohexyl phenyl ketone; acetophenone-based compounds, such as methoxyacetophenone, 2,2-dimethoxy-2-phenylacetophenone, 2,2-diethoxyacetophenone, and 2-methyl-1-[4-(methylthio)-phenyl]-2-morpholinopropane-1-one; benzoin ether-based compounds, such as benzoin ethyl ether, benzoin isopropyl ether, and anisoin methyl ether; ketal-based compounds such as benzyl dimethyl ketal; aromatic sulfonyl chloride-based compounds such as 2-naphthalenesulfonyl chloride; photoactive oxime-based compounds such as 1-phenone-1,1-propanedione-2-(o-ethoxycarbonyl)oxime; benzophenone-based compounds, such as benzophenone, benzoylbenzoic acid, and 3,3′-dimethyl-4-methoxybenzophenone; thioxanthone-based compounds, such as thioxanthone, 2-chlorothioxanthone, 2-methylthioxanthone, 2,4-dimethylthioxanthone, isopropylthioxanthone, 2,4-dichlorothioxanthone, 2,4-diethylthioxanthone, and 2,4-diisopropylthioxanthone; camphorquinone; halogenated ketones; and acyl phosphonates, and α-hydroxyacetophenones such as 2-hydroxy-1-(4-(4-(2-hydroxy-2-methylpropionyl)benzyl)phenyl)-2-methylpropane-1-one. Of those, 2,2-dimethoxy-2-phenylacetophenone, 2-hydroxy-1-(4-(4-(2-hydroxy-2-methylpropionyl)benzyl)phenyl-2-methylpropane-1-one, or the like may be preferably used. The photopolymerization initiators may be used alone or in combination thereof.

A commercially available product is used as the photopolymerization initiator. Examples thereof include products available under the product names “Omnirad 127D”, “Omnirad 651”, “Omnirad 369E”, “Omnirad 819”, and “Omnirad 2959” from IGM Resins B. V.

The photopolymerization initiator may be used in any appropriate amount. The content of the photopolymerization initiator is preferably from 0.3 part by weight to 10 parts by weight, more preferably from 0.5 part by weight to 7 parts by weight with respect to 100 parts by weight of the base polymer. When the content of the photopolymerization initiator is less than 0.3 part by weight, the pressure-sensitive adhesive may not be sufficiently cured at the time of UV irradiation. When the content of the photopolymerization initiator is more than 10 parts by weight, the storage stability of the pressure-sensitive adhesive may be reduced.

### C-3. Additive

The pressure-sensitive adhesive may contain any appropriate additive as required. Examples of the additive include a cross-linking agent, a catalyst (e.g., a platinum catalyst), a tackifier, a plasticizer, a pigment, a dye, a filler, an age resistor, a conductive material, a UV absorber, a light stabilizer, a peeling modifier, a softener, a surfactant, a flame retardant, and a solvent.

In at least one embodiment of the present invention, the pressure-sensitive adhesive further contains a cross-linking agent. Examples of the cross-linking agent include an isocyanate-based cross-linking agent, an epoxy-based cross-linking agent, an aziridine-based cross-linking agent, and a chelate-based cross-linking agent. The content ratio of the cross-linking agent is preferably from 0.01 part by weight to 10 parts by weight, more preferably from 0.02 part by weight to 5 parts by weight, still more preferably from 0.025 part by weight to 3 parts by weight with respect to 100 parts by weight of the base polymer in the pressure-sensitive adhesive. The flexibility of the pressure-sensitive adhesive layer may be controlled by the content ratio of the cross-linking agent. When the content of the cross-linking agent is less than 0.01 part by weight, the pressure-sensitive adhesive becomes sol, and hence the pressure-sensitive adhesive layer may not be formed. When the content of the cross-linking agent is more than 10 parts by weight, adhesiveness to an adherend such as a semiconductor wafer may be reduced, and hence the semiconductor wafer may not be sufficiently protected.

In at least one embodiment of the present invention, an isocyanate-based cross-linking agent is preferably used. The isocyanate-based cross-linking agent is preferred because the cross-linking agent can react with various kinds of functional groups. A cross-linking agent having 3 or more isocyanate groups is particularly preferably used. When the isocyanate-based cross-linking agent is used as the cross-linking agent and the content ratio of the cross-linking agent falls within the above-mentioned ranges, a pressure-sensitive adhesive layer that is excellent in peelability even after heating and that causes a remarkably reduced adhesive residue can be formed.

The thickness of the pressure-sensitive adhesive layer may be set to any appropriate value. The thickness of the pressure-sensitive adhesive layer is preferably from 1 μm to 50 μm, more preferably from 2 μm to 50 μm, still more preferably from 4 μm to 30 μm. When the thickness of the pressure-sensitive adhesive layer falls within the above-mentioned ranges, a sufficient pressure-sensitive adhesive strength to an adherend such as a semiconductor wafer can be exhibited.

The pressure-sensitive adhesive layer may have any appropriate pressure-sensitive adhesive strength. The pressure-sensitive adhesive strength of the pressure-sensitive adhesive layer to a silicon wafer before active energy ray irradiation is preferably from 0.50 N/20 mm to 30 N/20 mm, more preferably from 2 N/20 mm to 25 N/20 mm, still more preferably from 3 N/20 mm to 25 N/20 mm. Herein, the pressure-sensitive adhesive strength of the pressure-sensitive adhesive layer refers to a value measured as follows: the pressure-sensitive adhesive tape is cut out into a size measuring 20 mm wide by 80 mm long; the pressure-sensitive adhesive layer of the pressure-sensitive adhesive tape for semiconductor wafer processing is pressure-bonded to a mirror surface of a silicon mirror wafer by reciprocating a 2-kilogram roller once under an atmosphere at 23° C.; the resultant is left to stand at 23° C. for 30 minutes; and then measurement is performed by a 180° peel test under an atmosphere at 23° C. and 50% RH and under the condition of a tensile rate of 300 mm/min.

The pressure-sensitive adhesive strength of the pressure-sensitive adhesive layer to a silicon wafer after active energy ray irradiation (for example UV irradiation) is preferably 0.1 N/20 mm or less, more preferably from 0.001 N/20 mm to 0.1 N/20 mm, still more preferably from 0.001 N/20 mm to 0.08 N/20 mm, particularly preferably from 0.001 N/20 mm to 0.05 N/20 mm. The pressure-sensitive adhesive strength after active energy ray irradiation refers to a value measured as follows: the pressure-sensitive adhesive tape is cut out into a size measuring 20 mm wide by 80 mm long, and the pressure-sensitive adhesive layer is pressure-bonded to the mirror surface of the silicon mirror wafer by reciprocating a 2-kilogram roller once under an atmosphere at 23° C.; the resultant is left to stand at 23° C. for 30 minutes; then the pressure-sensitive adhesive layer is irradiated with UV light (UV) from a substrate side of the pressure-sensitive adhesive tape for semiconductor wafer processing so that the integrated light quantity becomes 1,000 mJ/cm² (converted to wavelength of 365 nm); and then measurement is performed by performing a 180° peel test under an atmosphere at 23° C. and 50% RH and under the condition of a tensile rate of 300 mm/min.

### D. Release Liner

The pressure-sensitive adhesive tape may be kept under a state in which a release liner is bonded to the pressure-sensitive adhesive layer to protect the pressure-sensitive adhesive layer until practical use. The release liner typically includes a substrate film and a release treatment layer. Any appropriate release agent may be used as a release agent forming the release treatment layer. Examples thereof include a silicone-based release agent, a fluorine-based release agent, and a long-chain alkyl acrylate-based release agent.

Any appropriate film may be used as the substrate film. Examples thereof include a plastic (e.g., polyethylene terephthalate (PET), polyethylene, or polypropylene) film, a nonwoven fabric, and paper.

The release treatment layer may be formed by applying a composition containing the release agent to the substrate film. The thickness of the release treatment layer is preferably 0.05 μm or less, more preferably from 0.001 μm to 0.05 μm. When the thickness of the release treatment layer falls within the above-mentioned ranges, transfer of the release agent or the like from the release liner to the surface of the pressure-sensitive adhesive layer is suppressed, and as a result, contamination of the adherend surface by foreign matter derived from the pressure-sensitive adhesive tape can be suppressed.

An amount of silicone present on the surface of the pressure-sensitive adhesive layer after peeling of the release liner is preferably 2.0 mg/m² or less, more preferably 1.8 mg/m² or less, still more preferably 1.5 mg/m² or less. The amount of silicone present on the surface of the pressure-sensitive adhesive layer is preferably as small as possible, and is, for example, 0.5 mg/m² or more. Herein, the amount of silicone present on the surface of the pressure-sensitive adhesive layer after peeling of the release liner refers to an amount of silicone per unit area in terms of polydimethylsiloxane present on the surface of the pressure-sensitive adhesive layer when the release liner is peeled at a tensile rate of 300 mm/min and a peel angle of 180°. The term “per unit area” refers to per unit area of the pressure-sensitive adhesive layer in a portion where the pressure-sensitive adhesive layer and the release liner are bonded to each other. The amount of silicone transfer may be determined by a method using X-ray fluorescence analysis.

A liner peel strength of the release liner is preferably 0.2 N/50 mm or less, preferably 0.18 N/50 mm or less, still more preferably 0.16 N/50 mm or less. The liner peel strength is preferably as low as possible, and is, for example, 0.05 N/50 mm or more. Herein, the liner peel strength refers to a value measured by the following method.

### <Liner Peel Strength>

A laminate of a pressure-sensitive adhesive tape and a release liner is cut out into a size with a width of 50 mm to provide a sample. A surface of the substrate on which no pressure-sensitive adhesive layer is formed and a stainless-steel (SUS) plate are fixed with a double-sided tape, the release liner is peeled at a peel rate of 300 mm/min to perform a 180° peel test, and the obtained value is defined as the liner peel strength.

### E. Method of Producing Pressure-Sensitive Adhesive Tape

The pressure-sensitive adhesive tape may be produced by any appropriate method. In at least one embodiment of the present invention, the pressure-sensitive adhesive tape may be produced by, for example, forming a pressure-sensitive adhesive layer on a substrate including any appropriate anchor coat layer. When the substrate includes an anchor coat layer, the pressure-sensitive adhesive layer is formed on the anchor coat layer. The pressure-sensitive adhesive layer may be formed by applying a composition for forming a pressure-sensitive adhesive layer to the substrate, or may be formed by forming a pressure-sensitive adhesive layer on any appropriate release liner, followed by transfer of the pressure-sensitive adhesive layer to the substrate. Various methods, such as bar coater coating, air knife coating, gravure coating, gravure reverse coating, reverse roll coating, lip coating, die coating, dip coating, offset printing, flexographic printing, and screen printing, may each be adopted as a coating method.

### F. Application of Pressure-Sensitive Adhesive Tape

The pressure-sensitive adhesive tape according to at least one embodiment of the present invention can be used for any appropriate application. For example, the pressure-sensitive adhesive tape can be suitably used in a production process for a semiconductor device. The pressure-sensitive adhesive tape according to at least one embodiment of the present invention can be suitably used as a backgrinding tape. The backgrinding tape is required to have such easy peelability as to appropriately hold a silicon wafer at the time of backgrinding and to be capable of being peeled without causing an adhesive residue and without breaking the ground wafer at the time of its peeling. The pressure-sensitive adhesive tape according to at least one embodiment of the present invention can be suppressed from causing an adhering substance derived from the pressure-sensitive adhesive and an adhesive residue on a surface of a semiconductor wafer. Accordingly, the pressure-sensitive adhesive tape according to at least one embodiment of the present invention can be suitably used for semiconductor wafer processing, particularly as a backgrinding tape.

### EXAMPLES

The present invention is specifically described below by way of Examples, but the present invention is not limited to these Examples. In addition, “part(s)” and “%” in Examples are by weight unless otherwise stated.

### Synthesis Example 1: Synthesis of Polymer A

100 Parts by weight of 2-ethylhexyl acrylate (2EHA) and 27 parts by weight of 2-hydroxyethyl acrylate (HEA) (manufactured by Toagosei Co., Ltd., product name: ACRYCS (trademark) HEA) were each used as a monomer component. 0.2 wt % of a polymerization initiator (manufactured by NOF Corporation, product name: NYPER BW) with respect to the total weight of the monomer components and 155 parts by weight of a solvent (ethyl acetate) were mixed to prepare a monomer composition (solid content concentration: 45%). The resultant monomer composition was loaded into an experimental apparatus for polymerization including a 1-liter round-bottom separable flask with a separable cover, a separating funnel, a temperature gauge, a nitrogen-introducing tube, a Liebig condenser, a vacuum seal, a stirring rod, and a stirring blade. While the composition was stirred, the apparatus was purged with nitrogen at normal temperature for 1 hour. After that, while the composition was stirred in a stream of nitrogen, the composition was held at 60° C. for 4 hours for solution polymerization to provide a polymer solution. An aging step was not performed.

The resultant polymer solution was cooled to 35° C. or less, and was stirred for 15 minutes or more while oxygen was introduced into the flask. After that, 2-methacryloyloxyethyl isocyanate (hereinafter referred to as “MOI”) (manufactured by Resonac Corporation, product name: “Karenz MOI”) was added in an amount of 80 mol % in terms of moles with respect to the addition amount of HEA. In addition, 0.03 wt % of dibutyltin dilaurate with respect to the addition amount of MOI was added as a reaction catalyst. After that, the contents were subjected to addition reaction treatment (urethanization reaction) at 50° C. for 12 hours in a stream of air to provide an acrylic copolymer having a polymerizable carbon-carbon double bond introduced thereinto. The weight-average molecular weight of the resultant polymer was 800,000. The MOI addition amount refers to a ratio (mol %) of hydroxy groups including MOI added thereto out of all hydroxy groups of the base polymer.

### Synthesis Examples 2 to 7: Synthesis of Polymers B to E

Polymers B to E were each obtained in the same manner as in Synthesis Example 1 except that the monomer composition, the polymerization conditions, and the MOI addition amount were changed as shown in Table 1.

### <Measurement of Weight-Average Molecular Weight and Molecular Weight Distribution>

The weight-average molecular weight and number-average molecular weight of each of the polymers obtained in Synthesis Examples A to G were measured with a GPC (manufactured by Agilent Technologies, Inc., product name: “1260 Infinity”). The weight-average molecular weight and the number-average molecular weight were defined as values in terms of polystyrene.

TABLE 1

| | | A | B | C | D | E | F | G |
|---|---|---|---|---|---|---|---|---|
| Polymerization | 2EHA | 100 | 100 | 100 | 100 | 100 | 100 | 30 |
| materials (parts by | MA | — | — | — | — | — | | 70 |
| weight) | ACMO | — | 25.5 | 25.5 | — | 25.5 | 25.5 | — |
| | AA | — | — | — | — | — | | 10 |
| | HEA | 27 | 18.5 | 18.5 | 27 | 18.5 | 18.5 | — |
| | NYPER BW | 0.2% | 0.2% | 0.2% | 0.2% | 0.2% | 0.2% | 0.5% |
| | Toluene | — | 78 | 78 | — | 118 | 118 | — |
| | Ethyl acetate | 155 | — | — | 190 | — | — | 155 |
| Polymerization | First stage | 60° C. | 60° C. | 60° C. | 60° C. | 60° C. | 60° C. | 60° C. |
| conditions | | 4 hours | 4 hours | 4 hours | 5 hours | 5 hours | 24 hours | 7 hours |
| | Second stage | — | — | — | 75° C. | 75° C. | — | 80° C. |
| | | | | | 3 hours | 3 hours | | 3 hours |
| | Solid content | 45 | 65 | 65 | 40 | 55 | 55 | 41.5 |
| | concentration (wt %) | | | | | | | |

| | | | | | | | |
|---|---|---|---|---|---|---|---|
| MOI addition amount (mol %) | 80 | 90 | 70 | 80 | 90 | 80 | — |
| Weight-average molecular weight | 800,000 | 650,000 | 650,000 | 400,000 | 400,000 | 400,000 | 1,000,000 |
| Mw/Mn | 2.4 | 4.2 | 4.2 | 5.6 | 7 | 6.9 | 5.5 |

2EHA: 2-ethylhexyl acrylate
MA: methacrylic acid
ACMO: acryloylmorpholine
AA: acrylic acid
HEA: 2-hydroxyethyl acrylate
NYPER BW: manufactured by NOF Corporation, product name: NYPER BW

### Example 1

### 1. Preparation of Pressure-Sensitive Adhesive

3 Parts by weight of a photopolymerization initiator (manufactured by IGM Resins B. V., product name: “Omnirad 127D”) and 0.5 part by weight of a cross-linking agent (manufactured by Mitsui Chemicals, Inc., product name: “TAKENATE D-101A”) were added to 100 parts by weight of Polymer A to prepare a pressure-sensitive adhesive composition.

### 2. Production of Pressure-Sensitive Adhesive Tape

The resultant pressure-sensitive adhesive composition was applied to a release treatment surface of a release liner (manufactured by Teijin Film Solutions Limited, Purex SRD38, thickness of release treatment layer: 0.02 μm) having a thickness of 38 μm, and the resultant was heated at 120° C. for 120 seconds so that its solvent was removed. Thus, a pressure-sensitive adhesive layer having a thickness of 10 μm was formed.

Next, the pressure-sensitive adhesive layer was bonded to an anchor coat layer side surface of a substrate including an anchor coat layer (PET film manufactured by Mitsubishi Chemical Corporation, product name: T910E50, including an anchor coat layer and having a thickness of 50 μm) to transfer the pressure-sensitive adhesive layer, and the resultant was kept at 50° C. for 72 hours. Thus, a pressure-sensitive adhesive tape including the substrate and the pressure-sensitive adhesive layer in the stated order was obtained.

### Examples 2 to 6

Pressure-sensitive adhesive tapes were each obtained in the same manner as in Example 1 except that the composition of the pressure-sensitive adhesive was changed as shown in Table 2.

TABLE 2

| | | | Example 1 | Example 2 | Example 3 | Example 4 | Example 5 | Example 6 |
|---|---|---|---|---|---|---|---|---|
| Pressure- | Polymer | A | 100 | — | — | — | — | — |
| sensitive | | B | — | 100 | 100 | 100 | 100 | — |
| adhesive | | C | — | — | — | — | — | 100 |
| | | D | — | — | — | — | — | — |
| | | E | — | — | — | — | — | — |
| | | F | — | — | — | — | — | — |
| | | G | — | — | — | — | — | — |
| | Photopolymerization | Omnirad 127D | 3 | 1 | 3 | — | — | 3 |
| | initiator | Omnirad 2959 | — | — | — | 3 | — | — |
| | | Omnirad 651 | — | — | — | — | 3 | — |
| | Cross-linking agent | TAKENATE | 0.5 | 1 | 1 | 1 | 1 | 1 |
| | | D-101A | | | | | | |
| | UV-curable resin | DPHA | — | — | — | — | — | — |
| Substrate | | Kind | T910E50 | | | | | |
| Release liner | | Kind | SRD38 | | | | | |
| | | Coating | 0.02 | | | | | |
| | | thickness | | | | | | |
| | | (μm) | | | | | | |
| Properties | 180° pressure- | Before UV | 3.2 | 15.3 | 15.3 | 16.0 | 15.8 | 17.0 |
| | sensitive adhesive | After UV | 0.04 | 0.04 | 0.02 | 0.03 | 0.04 | 0.08 |
| | strength | | | | | | | |
| | (N/20 mm) | | | | | | | |
| | Silicone transfer amount (mg/m²) | | 0.7 | 1.5 | 1.6 | 1.5 | 1.5 | 1.5 |
| | Liner peel strength (N/50 mm) | | 0.10 | 0.15 | 0.15 | 0.16 | 0.15 | 0.16 |
| | Gel fraction | G₁ before UV | 88% | 93% | 92% | 92% | 92% | 92% |
| | | G₂ after UV | 96% | 97% | 98% | 96% | 98% | 96% |
| | Before UV S₁ | Mw/Mn | 2.0 | 1.8 | 1.8 | 1.8 | 1.8 | 1.6 |
| | (UV detection) | | | | | | | |
| | After UV Sol S₂ | Mw: 1,000 to | 3% | —* | —* | —* | 3% | 3% |
| | (RI detection) | 10,000 | | | | | | |

| | | | | | | |
|---|---|---|---|---|---|---|
| Total amount of particles | 89 | 19 | 45 | 29 | 66 | 14 |
| (particles/8 inch) | | | | | | |

| | | | Comparative | Comparative | Comparative | Comparative |
|---|---|---|---|---|---|---|
| | | | Example 1 | Example 2 | Example 3 | Example 4 |
| Pressure- | Polymer | A | — | — | — | — |
| sensitive | | B | — | — | — | — |
| adhesive | | C | — | — | — | — |
| | | D | 100 | — | — | — |
| | | E | — | 100 | — | — |
| | | F | — | — | 100 | — |
| | | G | — | — | — | 100 |
| | Photopolymerization | Omnirad 127D | 3 | 3 | 3 | 3 |
| | initiator | Omnirad 2959 | — | — | — | — |
| | | Omnirad 651 | — | — | — | — |
| | Cross-linking agent | TAKENATE | 0.5 | 1 | 1 | 1 |
| | | D-101A | | | | |
| | UV-curable resin | DPHA | — | — | — | 50 |
| Substrate | | Kind | T910E50 | | | |
| Release liner | | Kind | SRD38 | | | |
| | | Coating | 0.02 | | | |
| | | thickness | | | | |
| | | (μm) | | | | |
| Properties | 180° pressure- | Before UV | 4.1 | 15.0 | 15.8 | 8 |
| | sensitive adhesive | After UV | 0.03 | 0.04 | 0.05 | 0.04 |
| | strength | | | | | |
| | (N/20 mm) | | | | | |

| Silicone transfer amount (mg/m²) | | 0.7 | 1.5 | 1.5 | 3.0 |
|---|---|---|---|---|---|
| Liner peel strength (N/50 mm) | | 0.10 | 0.14 | 0.15 | 0.2 |
| Gel fraction | G₁ before UV | 82% | 92% | 90% | 58% |
| | G₂ after UV | 97% | 96% | 96% | 98% |
| Before UV S₁ | Mw/Mn | 2.2 | 3.5 | 3.4 | 4.5 |
| (UV detection) | | | | | |
| After UV Sol S₂ | Mw: 1,000 to | 100% | 98% | 98% | 100% |
| (RI detection) | 10,000 | | | | |

| | | | | |
|---|---|---|---|---|
| Total amount of particles | 5,609 | 1,472 | 2,250 | 8,808 |
| (particles/8 inch) | | | | |

*Below detection limit
Omnirad 2959: manufactured by IGM Resins B.V.
Omnirad 651: manufactured by IGM Resins B.V.

### Comparative Examples 1 to 4

Pressure-sensitive adhesive tapes were each obtained in the same manner as in Example 1 except that the composition of the pressure-sensitive adhesive was changed as shown in Table 2. In Comparative Example 2, 50 parts by weight of dipentaerythritol hexaacrylate (DPHA) (manufactured by Nippon Kayaku Co., Ltd., product name: “KAYARAD DPHA”) was further added to prepare a pressure-sensitive adhesive composition.

### <Evaluation>

The following evaluations were performed by using the pressure-sensitive adhesive tapes obtained in Examples and Comparative Examples. The results are shown in Table 2.

### 1. Pressure-Sensitive Adhesive Strength

A Si mirror wafer (manufactured by Shin-Etsu Chemical Co., Ltd.) was subjected to pretreatment involving washing with toluene, ethanol, and toluene in the stated order, and drying. Next, the pressure-sensitive adhesive layer of the pressure-sensitive adhesive tape of each of Examples or Comparative Examples was bonded to the wafer. The resultant was stored at normal temperature for 30 minutes. After that, a pressure-sensitive adhesive strength was measured under the following conditions (pressure-sensitive adhesive strength before UV). The pressure-sensitive adhesive tape was similarly bonded to the wafer, and the pressure-sensitive adhesive tape was subjected to UV irradiation (integrated light quantity: 460 mJ/cm²) from its substrate side with a high-pressure mercury lamp (UV irradiance: 40 mW/cm², manufactured by Nitto Seiki Co., Ltd., product name: UM-810) for about 10 seconds. Next, a pressure-sensitive adhesive strength was measured under the following conditions (pressure-sensitive adhesive strength after UV).

### <Pressure-Sensitive Adhesive Strength Measurement Conditions>

Tensile rate: 300 mm/min
Peel angle: 180°
Temperature: 23° C.
Humidity: 50% RH
Tape width: 20 mm
Tape length: 80 mm

### 2. Silicone Transfer Amount

The resultant pressure-sensitive adhesive tape with a release liner was cut out into a size measuring 50 mm by 50 mm to provide a measurement sample. The release liner was peeled from the measurement sample at a tensile rate of 300 mm/min and a peel angle of 180°. An amount of Si present per area corresponding to a circle having a diameter of 30 mm of the exposed pressure-sensitive adhesive surface was determined from an X-ray intensity (cps: counts per second) measured with an X-ray fluorescence analyzer. From the X-ray intensity (cps) of the pressure-sensitive adhesive surface of the resultant pressure-sensitive adhesive layer, the amount of silicone on the pressure-sensitive adhesive layer (silicone transfer amount, g/m²) was determined in terms of polydimethylsiloxane. The amount of silicone was calculated from the conversion formula: 100 kcps=0.60 g/m². The X-ray intensity was measured with an X-ray fluorescence analyzer (manufactured by RIGAKU Corporation, product name: “ZSX Primus IV”) by using a vertical Rh tube as an X-ray source and RX-4 as a spectroscopic crystal, and setting an output to 46 mA at 50 kV.

### 3. Liner Peel Strength

The pressure-sensitive adhesive tape with a release liner was cut out into a size with a width of 50 mm to provide a sample. A surface of the substrate on which the pressure-sensitive adhesive layer was not formed and a SUS plate were fixed with a double-sided tape. Next, the release liner was peeled at a peel rate of 300 mm/min and an peel angle of 180°, and the obtained value was defined as the liner peel strength.

### 4. Gel Fraction

About 0.2 g of a sample was collected from the pressure-sensitive adhesive layer of the pressure-sensitive adhesive tape. Next, the sample was wrapped with a mesh-like sheet (manufactured by Nitto Denko Corporation, product name: NTF1122, thickness: 80 μm, average pore diameter: 0.2 μm), and the resultant was then immersed in about 30 mL of ethyl acetate at room temperature for 1 week. After that, the mesh-like sheet was taken out from ethyl acetate, and an ethyl acetate-insoluble content included in the mesh-like sheet was recovered. The recovered ethyl acetate-insoluble content was dried at normal pressure and 130° C. for about 2 hours. The ethyl acetate-insoluble content was weighed. A gel fraction G₁ was determined by calculating a weight ratio of a gel component by the following equation.

$$Gel fraction ( \% ) = [ ( weighed value ( g ) of ethyl acetate - insoluble content ) / ( weight ( g ) of acquired sample ) ] \times 100$$

UV irradiation (integrated light quantity: 460 mJ/cm²) was performed with a high-pressure mercury lamp (UV irradiance: 40 mW/cm², manufactured by Nitto Seiki Co., Ltd., product name: UM-810) for about 10 seconds from the substrate side of the resultant pressure-sensitive adhesive tape with a release liner. Next, the release liner was peeled from the pressure-sensitive adhesive tape. About 0.02 g of a sample was collected from the pressure-sensitive adhesive layer, and a gel fraction G₂ was similarly calculated.

### 5. Measurement of Component Having Weight-Average Molecular Weight of 1,000 or More and 10,000 or Less in Sol S₂

The resultant pressure-sensitive adhesive tape with a release liner was cut out into a size measuring 5 cm by 5 cm to provide a sample. UV irradiation (integrated light quantity: 460 mJ/cm²) was performed with a high-pressure mercury lamp (UV irradiance: 40 mW/cm², manufactured by Nitto Seiki Co., Ltd., product name: UM-810) for about 10 seconds on the pressure-sensitive adhesive tape from the substrate side. Next, the release liner was peeled from the sample. A sample was collected from the pressure-sensitive adhesive layer of the pressure-sensitive adhesive tape after active energy ray irradiation. Tetrahydrofuran (THF) was added to the sample so that a sol content S₂ concentration became 0.1 wt % to prepare a sample, and the sample was left to stand still for 1 day for dissolution. Next, the resultant sample was filtered through use of a 0.45 μm membrane filter. The filtrate was subjected to GPC measurement under the following conditions, and an area ratio of a component having a weight-average molecular weight (Mw) of 1,000 or more and 10,000 or less was calculated from the obtained molecular weight distribution curve. The sol content S₂ concentration was calculated by the following equation. A method of measuring a gel fraction G₂ is as described later.

$$Sol content {S}_{2} concentration ( wt \% ) = 100 ( wt \% ) - gel fraction {G}_{2} ( wt \% )$$

### <GPC Measurement Conditions>

Apparatus: manufactured by Agilent Technologies, Inc., product
name: “1260 Infinity”
Column: manufactured by Tosoh Corporation, TSKgel GMH-H(S)
Flow rate: 0.5 ml/min
Column temperature: 40° C.
Eluent: THF
Injection amount: 100 μL
Injected sample concentration: 0.1 wt %
Detector: RI detector

### 6. Measurement of Molecular Weight Distribution of Sol Content S₁

The pressure-sensitive adhesive tape obtained in each of Examples or Comparative Examples was cut out into a size measuring 5 cm by 5 cm, and then the release liner was peeled from the sample. The pressure-sensitive adhesive was collected from the pressure-sensitive adhesive layer of the pressure-sensitive adhesive tape. Tetrahydrofuran (THF) was added to the pressure-sensitive adhesive so that a sol content S₁ concentration became 0.1 wt % to prepare a sample, and the sample was left to stand still for 1 day for dissolution. Next, the resultant sample was filtered through use of a 0.45 μm membrane filter. The filtrate was subjected to GPC measurement under the following conditions, and the molecular weight distribution was determined from the obtained molecular weight distribution curve. The sol content S₁ concentration was calculated by the following equation. A method of measuring a gel fraction G₁ is as described later.

$$Sol content {S}_{1} concentration ( wt \% ) = 100 ( wt \% ) - gel fraction {G}_{1} ( wt \% )$$

### <GPC Measurement Conditions>

Apparatus: manufactured by Agilent Technologies, Inc., product
name: “1260 Infinity”
Column: manufactured by Tosoh Corporation, product name: “TSKgel
GMH-H (S)”
Flow rate: 0.5 ml/min
Column temperature: 40° C.
Eluent: THF
Injection amount: 100 μL
Injected sample concentration: 0.1 wt %
Detector: RI detector

### 7. Number of Particles

In a clean bench, the release liner was peeled from the resultant pressure-sensitive adhesive tape, and the pressure-sensitive adhesive layer side of the pressure-sensitive adhesive tape was bonded to an unused silicon mirror wafer (8 inches). After that, the pressure-sensitive adhesive tape was stored for 30 minutes. After that, the pressure-sensitive adhesive tape was subjected to UV irradiation (integrated light quantity: 460 mJ/cm²) from its substrate side with a high-pressure mercury lamp (UV irradiance: 40 mW/cm², manufactured by Nitto Seiki Co., Ltd., product name: “UM-810”) for about 10 seconds. Next, the pressure-sensitive adhesive tape was peeled from the silicon mirror wafer, and the number of particles on the surface of the silicon wafer was measured under the following conditions.

### <Measurement Conditions>

Measurement apparatus: wafer inspection apparatus “Surfscan SP1” (manufactured by KLA-Tencor Corporation)
Light source: argon ion laser (wavelength: 488 nm)
Laser irradiation angle: Normal (laser perpendicular irradiation)
Edge cut: 50 mm
Measured particle size range: The total number of particles measured in the range of 0.2 μm or more was defined as the number of particles.

In the pressure-sensitive adhesive tape of each of Examples of the present invention, the ratio of the component having a weight-average molecular weight of 1,000 or more and 10,000 or less in the sol content S₂ of the pressure-sensitive adhesive layer after active energy ray irradiation was suppressed. In addition, an adhering substance on the surface of the wafer serving as an adherend was suppressed.

The pressure-sensitive adhesive tape according to at least one embodiment of the present invention can be suitably used in an application for semiconductor wafer processing. For example, the pressure-sensitive adhesive tape can be suitably used as a backgrinding tape for semiconductor wafer processing.

According to at least one embodiment of the present invention, the pressure-sensitive adhesive tape, which has suppressed contamination of an adherend surface after peeling, can be provided.

What is claimed is:

1. A pressure-sensitive adhesive tape, comprising:
a substrate; and
a pressure-sensitive adhesive layer formed of an active energy ray-curable pressure-sensitive adhesive,
wherein a ratio of a component having a weight-average molecular weight of 1,000 or more and 10,000 or less in a sol content S₂ of the pressure-sensitive adhesive layer after active energy ray irradiation is 5% or less.

2. The pressure-sensitive adhesive tape according to claim 1, wherein a molecular weight distribution of a component having a weight-average molecular weight of 1,000 or more and 10,000 or less in a sol content S₁ of the pressure-sensitive adhesive layer before active energy ray irradiation is 2.0 or less.

3. The pressure-sensitive adhesive tape according to claim 1, wherein the active energy ray-curable pressure-sensitive adhesive contains a polymer having a polymerizable carbon-carbon double bond group at at least one of a terminal thereof or a side chain thereof.

4. The pressure-sensitive adhesive tape according to claim 3, wherein the polymer having a polymerizable carbon-carbon double bond group at at least one of a terminal thereof or a side chain thereof has a weight-average molecular weight of from 300,000 to 1,500,000.

5. The pressure-sensitive adhesive tape according to claim 3, wherein the polymer having a polymerizable carbon-carbon double bond group at at least one of a terminal thereof or a side chain thereof has a molecular weight distribution of 5.0 or less.

6. The pressure-sensitive adhesive tape according to claim 1, wherein a pressure-sensitive adhesive strength of the pressure-sensitive adhesive layer to a silicon wafer after active energy ray irradiation is 0.1 N/20 mm or less.

7. The pressure-sensitive adhesive tape according to claim 1, wherein a gel fraction G₂ of the pressure-sensitive adhesive layer after active energy ray irradiation is 90% or more.

8. The pressure-sensitive adhesive tape according to claim 3, wherein the polymer having a polymerizable carbon-carbon double bond group at at least one of a terminal thereof or a side chain thereof is an acrylic polymer.

9. The pressure-sensitive adhesive tape according to claim 1, wherein the active energy ray-curable pressure-sensitive adhesive further contains an isocyanate-based cross-linking agent.

10. The pressure-sensitive adhesive tape according to claim 1, wherein the substrate is a substrate formed of a polyester-based resin.

11. The pressure-sensitive adhesive tape according to claim 1,
wherein the substrate further includes an anchor coat layer, and
wherein the pressure-sensitive adhesive layer is laminated on the anchor coat layer.

12. The pressure-sensitive adhesive tape according to claim 11, wherein the anchor coat layer contains a thermosetting resin.

13. The pressure-sensitive adhesive tape according to claim 12, wherein the anchor coat layer contains a thermosetting resin having an oxazoline group.

14. The pressure-sensitive adhesive tape according to claim 1, further comprising a release liner laminated on the pressure-sensitive adhesive layer, wherein the release liner includes a release treatment layer having a thickness of 0.05 μm or less.

15. The pressure-sensitive adhesive tape according to claim 14, wherein an amount of silicone present on a surface of the pressure-sensitive adhesive layer after peeling of the release liner is 2.0 mg/m² or less.

16. The pressure-sensitive adhesive tape according to claim 14, wherein the release liner has a liner peel strength of 0.2 N/50 mm or less.

17. The pressure-sensitive adhesive tape according to claim 1, wherein the pressure-sensitive adhesive tape is used for a semiconductor wafer processing process.
